(19) United States
(12) Patent Application Publication
(10) Pub. No.: US 2010/0157535 A1
(43) Pub. Date: Jun. 24, 2010

(54) HEAT-TRANSPORTING DEVICE AND ELECTRONIC APPARATUS

(75) Inventors: Kazunao Oniki, Tokyo (JP); Takashi Yajima, Tokyo (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/635,136

(22) Filed: Dec. 10, 2009

(30) Foreign Application Priority Data
Dec. 24, 2008 (JP) 2008-328871

(51) Int. Cl. F28D 15/04; F28D 15/00; H05K 7/20

(52) U.S. Cl. 361/700; 165/104.19; 165/104.21; 165/104.26

(57) ABSTRACT

A heat-transporting device includes a working fluid, a vessel, a vapor-phase flow path, a liquid-phase flow path, and an intermediate layer. The working fluid transports heat using a phase change. The vessel seals in the working fluid. The vapor-phase flow path causes the working fluid in a vapor phase to circulate inside the vessel. The liquid-phase flow path includes a first mesh member having a first mesh number and causes the working fluid in a liquid phase to circulate inside the vessel. The intermediate layer includes a second mesh member and is interposed between the liquid-phase flow path and the vapor-phase flow path, the second mesh member being laminated on the first mesh member and having a second mesh number smaller than the first mesh number.

### BACKGROUND OF THE INVENTION

1. Field of the Invention

The present invention relates to a heat-transporting device for transporting heat using a phase change of a working fluid and an electronic apparatus including the heat-transporting device.

2. Description of the Related Art

From the past, a heat pipe has been widely used as a device for transporting heat from a heat source such as a CPU (Central Processing Unit) of a PC (Personal Computer). As the heat pipe, a pipy heat pipe and a planar heat pipe are widely known. In such a heat pipe, a working fluid such as water is sealed inside and circulated while changing phases inside the heat pipe, to thus transport heat from a heat source such as a CPU. A driving source for circulating a working fluid needs to be provided inside the heat pipe, and a metal sintered body, a metal mesh, and the like for generating a capillary force are generally used.

For example, Japanese Patent Application Laid-open No. 2006-292355 (paragraphs (0003), (0010), and (0011), FIGS. 1, 3, and 4) discloses a heat pipe that uses a metal sintered body or a metal mesh.

### SUMMARY OF THE INVENTION

Incidentally, in recent years, along with an enhancement of performance of electronic components such as a CPU, a calorific value is on the increase. Along with such an increase in the calorific value of the electronic components such as a CPU, an enhancement of performance of a heat-transporting device that transports heat from the electronic components is demanded.

In view of the circumstances as described above, there is a need for a heat-transporting device having high heat-transporting performance and an electronic apparatus including the heat-transporting device.

According to an embodiment of the present invention, there is provided a heat-transporting device including a working fluid, a vessel, a vapor-phase flow path, a liquid-phase flow path, and an intermediate layer.

The working fluid transports heat using a phase change.

The vessel seals in the working fluid.

The vapor-phase flow path causes the working fluid in a vapor phase to circulate inside the vessel.

The liquid-phase flow path includes a first mesh member having a first mesh number and causes the working fluid in a liquid phase to circulate inside the vessel.

The intermediate layer includes a second mesh member and is interposed between the liquid-phase flow path and the vapor-phase flow path, the second mesh member being laminated on the first mesh member and having a second mesh number smaller than the first mesh number.

The “mesh number” refers to the number of meshes of a mesh member per inch (25.4 mm).

In the embodiment of the present invention, the intermediate layer is interposed between the vapor-phase flow path and the liquid-phase flow path. The mesh number of the second mesh member included in the intermediate layer is smaller than the mesh number of the first mesh member included in the liquid-phase flow path.

In other words, the mesh member of the intermediate layer is formed to have rougher meshes than the mesh member of the liquid-phase flow path. The meshes become rougher in the stated order of the liquid-phase flow path and the intermediate layer.

By providing the intermediate layer in the embodiment of the present invention, a capillary radius of the vapor-phase flow path can be practically widened. As a result, a pressure drop or the like in the vapor-phase flow path can be suppressed, and heat-transporting performance of the heat-transporting device can therefore be improved.

In the heat-transporting device, the vapor-phase flow path may include a third mesh member having a third mesh number smaller than the second mesh number.

Since the vapor-phase flow path is constituted of a mesh member in the embodiment of the present invention, durability of the heat-transporting device can be enhanced. For example, it is possible to prevent the vessel from being deformed by an internal pressure when heat is applied to the heat-transporting device.

Moreover, in the embodiment of the present invention, the mesh number of the third mesh member included in the vapor-phase flow path is smaller than the mesh number of the second mesh member included in the intermediate layer.

As a result, since meshes gradually become rougher in the stated order of the liquid-phase flow path, the intermediate layer, and the vapor-phase flow path, heat-transporting performance of the heat-transporting device can be improved efficiently.

In the heat-transporting device, the liquid-phase flow path may further include one or more mesh members that are disposed below the first mesh member such that mesh numbers thereof decrease stepwise from a lower layer adjacent to the vessel to an upper layer adjacent to the intermediate layer.

In the embodiment of the present invention, a plurality of mesh members are laminated in a multilayer to thus constitute the liquid-phase flow path. By the plurality of mesh members being arranged such that meshes thereof gradually become rougher from the lower layer to the upper layer, the heat-transporting performance of the heat-transporting device can be improved efficiently.

In the heat-transporting device, the mesh numbers of the mesh members except the mesh number of the mesh member positioned at the very bottom may decrease stepwise from the lower layer to the upper layer.

The mesh member positioned at the very bottom is in contact with an inner surface of the vessel. Therefore, a space between the mesh member at the very bottom and the inner surface of the vessel is smaller than spaces between the mesh members. Thus, it is possible to improve the heat-transporting performance of the heat-transporting device even if meshes of the mesh member at the very bottom is not the finest.

In the heat-transporting device, the vessel may be plate-like.

In the heat-transporting device, the vessel may include a first side that is in contact with a heat source and a second side on the other side of the first side.

In this case, the vapor-phase flow path may be disposed on the second side.

Also in this case, the liquid-phase flow path may be disposed on the first side.

As described above, in the heat-transporting device, meshes become rougher in the stated order of the liquid-phase flow path and the intermediate layer. Since the liquid-phase flow path side of the vessel is in contact with a heat source in the embodiment of the present invention, an evaporation area for the working fluid can be expanded stepwise toward the vapor-phase flow path side. As a result, the liquid-phase working fluid can be boiled efficiently, and the heat-transporting performance of the heat-transporting device can therefore be improved.

In the heat-transporting device, the vessel may be formed by bending a plate member so that the first mesh member and the second mesh member are sandwiched by the bent plate member.

With this structure, since the vessel can be formed of a single plate member, costs can be reduced.

In the heat-transporting device, the plate member may include an opening in an area where the plate member is bent.

With this structure, since the plate member can be easily bent, the heat-transporting device can be produced with ease.

According to another embodiment of the present invention, there is provided a heat-transporting device including a working fluid, a vessel, a vapor-phase flow path, a liquid-phase flow path, and an intermediate layer.

The working fluid transports heat using a phase change.

The vessel seals in the working fluid.

The vapor-phase flow path includes a first capillary radius and causes the working fluid in a vapor phase to circulate inside the vessel.

The liquid-phase flow path includes a second capillary radius and causes the working fluid in a liquid phase to circulate inside the vessel.

The intermediate layer includes a third capillary radius larger than the second capillary radius but smaller than the first capillary radius and is interposed between the liquid-phase flow path and the vapor-phase flow path.

In the embodiment of the present invention, the intermediate layer that has a capillary radius larger than the capillary radius of the liquid-phase flow path but smaller than the capillary radius of the vapor-phase flow path is provided. In this embodiment, the capillary radius of the vapor-phase flow path can be practically widened by the intermediate layer. As a result, a pressure drop or the like in the vapor-phase flow path can be suppressed, and the heat-transporting performance of the heat-transporting device can therefore be improved.

According to an embodiment of the present invention, there is provided an electronic apparatus including a heat source and a heat-transporting device.

The heat-transporting device includes a working fluid, a vessel, a vapor-phase flow path, a liquid-phase flow path, and an intermediate layer.

The working fluid transports heat of the heat source using a phase change.

The vessel seals in the working fluid.

The vapor-phase flow path causes the working fluid in a vapor phase to circulate inside the vessel.

The liquid-phase flow path includes a first mesh member having a first mesh number and causes the working fluid in a liquid phase to circulate inside the vessel.

The intermediate layer includes a second mesh member and is interposed between the liquid-phase flow path and the vapor-phase flow path, the second mesh member being laminated on the first mesh member and having a second mesh number smaller than the first mesh number.

According to another embodiment of the present invention, there is provided an electronic apparatus including a heat source and a heat-transporting device.

The heat-transporting device includes a working fluid, a vessel, a vapor-phase flow path, a liquid-phase flow path, and an intermediate layer.

The working fluid transports heat of the heat source using a phase change.

The vessel seals in the working fluid.

The vapor-phase flow path includes a first capillary radius and causes the working fluid in a vapor phase to circulate inside the vessel.

The liquid-phase flow path includes a second capillary radius and causes the working fluid in a liquid phase to circulate inside the vessel.

The intermediate layer includes a third capillary radius larger than the second capillary radius but smaller than the first capillary radius and is interposed between the liquid-phase flow path and the vapor-phase flow path.

As described above, according to the embodiments of the present invention, a heat-transporting device that has high heat-transporting performance and an electronic apparatus including the heat-transporting device can be provided.

These and other objects, features and advantages of the present invention will become more apparent in light of the following detailed description of best mode embodiments thereof, as illustrated in the accompanying drawings.

### BRIEF DESCRIPTION OF DRAWINGS

FIG. 1 is a perspective view of a heat-transporting device according to an embodiment of the present invention;

FIG. 2 is a cross-sectional side view of the heat-transporting device taken along the line A-A of FIG. 1;

FIG. 3 are enlarged plan views of an upper-layer mesh member and a lower-layer mesh member, respectively;

FIG. 4 are diagrams for explaining a capillary radius;

FIG. 5 is a cross-sectional side view of a general heat-transporting device;

FIG. 6 is a schematic diagram for explaining an operation of the general heat-transporting device;

FIG. 7 is a cooling model diagram of the general heat-transporting device;

FIG. 8 is a schematic diagram for explaining an operation of the heat-transporting device according to the embodiment of the present invention;

FIG. 9 is a diagram for explaining heat-transporting performance of a heat-transporting device according to the embodiment of the present invention, the diagram showing a maximum heat-transporting amount Qmax of a heat-transporting device including an intermediate layer and a heat-transporting device that does not include the intermediate layer;

FIG. 10 is a diagram obtained as a result of comparing a maximum heat-transporting amount Qmax in a case where mesh numbers increase stepwise from a lower layer and a maximum heat-transporting amount Qmax in a case where the mesh numbers decrease stepwise from the lower layer;

FIG. 11 is a cross-sectional side view of a heat-transporting device according to another embodiment of the present invention;

FIG. 12 is a diagram showing a maximum heat-transporting amount Qmax of the heat-transporting device according to the embodiment and the heat-transporting device that does not include an intermediate layer;

FIG. 13 is a diagram obtained as a result of comparing a maximum heat-transporting amount Qmax in a case where the mesh numbers increase stepwise from the lower layer and a maximum heat-transporting amount Qmax in a case where the mesh numbers decrease stepwise from the lower layer;

FIG. 14 is a cross-sectional side view of a heat-transporting device according to another embodiment of the present invention;

FIG. 15 is an enlarged cross-sectional diagram of a laminated body for explaining a reason why the mesh numbers except the mesh number of the lower-layer mesh member decrease stepwise from the lower layer;

FIG. 16 is a diagram for explaining heat-transporting performance of the heat-transporting device according to the embodiment;

FIG. 17 is a perspective view of a heat-transporting device according to another embodiment of the present invention;

FIG. 18 is a cross-sectional diagram taken along the line A-A of FIG. 17;

FIG. 19 is a cross-sectional side view of a heat-transporting device according to another embodiment of the present invention;

FIG. 20 is a perspective view of a heat-transporting device according to another embodiment of the present invention;

FIG. 21 is a cross-sectional diagram taken along the line A-A of FIG. 20;

FIG. 22 is a development view of a plate member that constitutes a vessel of the heat-transporting device according to the embodiment;

FIG. 23 are diagrams showing a method of producing the heat-transporting device according to the embodiment;

FIG. 24 is a development view of a plate member for explaining a heat-transporting device according to a modified example;

FIG. 25 is a perspective view of a heat-transporting device according to another embodiment of the present invention;

FIG. 26 is a cross-sectional diagram taken along the line A-A of FIG. 25;

FIG. 27 is a development view of a plate member that constitutes a vessel of the heat-transporting device according to the embodiment;

FIG. 28 is a perspective view of a laptop PC; and

FIG. 29 is a diagram showing a heat-transporting device in which a heat source is disposed on a vapor-phase flow path side.

### DESCRIPTION OF PREFERRED EMBODIMENTS

Hereinafter, embodiments of the present invention will be described with reference to the drawings.

### First embodiment

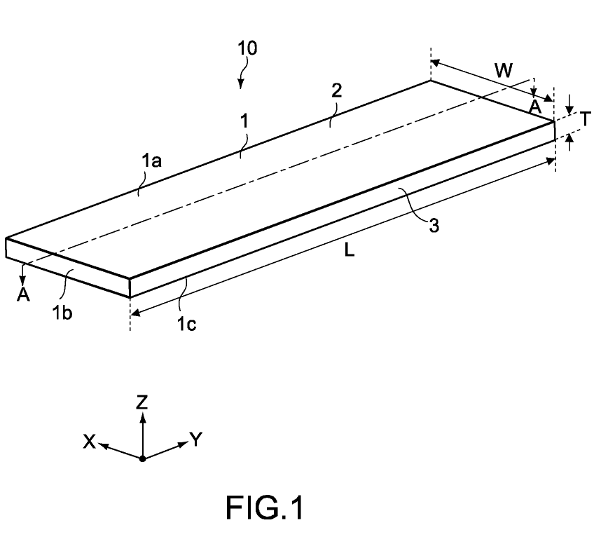

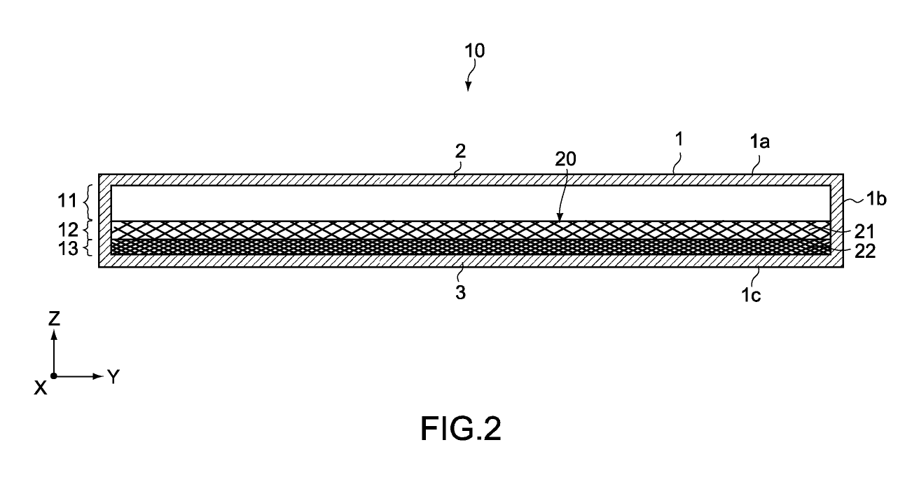

FIG. 1 is a perspective view of a heat-transporting device according to a first embodiment. FIG. 2 is a cross-sectional side view of the heat-transporting device taken along the line A-A of FIG. 1. It should be noted that in the specification, for brevity of descriptions on the figures, a heat-transporting device, components of the heat-transporting device, and the like may be illustrated in sizes different from actual sizes thereof.

As shown in the figures, a heat-transporting device 10 includes a thin rectangular plate-like vessel 1 that is elongated in one direction (y-axis direction).

The vessel 1 is formed by bonding an upper plate member 2 that constitutes an upper portion 1a of the vessel 1 and a lower plate member 3 that constitutes a circumferential side portion 1b and a lower portion 1c of the vessel 1, for example. A concave portion is formed in the lower plate member 3, and the concave portion forms a space inside the vessel 1.

Typically, the upper plate member 2 and the lower plate member 3 are made of oxygen-free copper, tough pitch copper, or a copper alloy. However, the materials are not limited thereto, and the upper plate member 2 and the lower plate member 3 may be made of metal other than copper, or a material having high heat conductivity may be used instead.

As a method of bonding the upper plate member 2 and the lower plate member 3, there are a diffusion bonding method, an ultrasonic bonding method, a brazing method, a welding method, and the like.

A length L of the vessel 1 (y-axis direction) is, for example, 10 mm to 500 mm, and a width W of the vessel 1 (x-axis direction) is, for example, 5 mm to 300 mm. Moreover, a thickness T of the vessel 1 (z-axis direction) is, for example, 0.3 mm to 5 mm. The length L, width W, and thickness T of the vessel 1 are not limited to those values and may of course take other values.

An inlet (not shown) that has a diameter of about 0.1 mm to 1 mm, for example, is provided in the vessel 1, and a working fluid is injected into the vessel 1 through this inlet. The working fluid is typically injected in a state where the vessel 1 is pressure-reduced inside.

Examples of the working fluid include pure water, alcohol such as ethanol, fluorine-based liquid such as Fluorinert FC72, and a mixture of pure water and alcohol.

The vessel 1 of the heat-transporting device 10 is hollow inside on the upper portion 1a side, and a laminated body 20 is disposed on the lower portion 1c side. The laminated body 20 is formed by laminating two mesh members 21 and 22. The mesh members 21 and 22 are each made of, for example, copper, phosphor bronze, aluminum, silver, stainless steel, molybdenum, or an alloy thereof.

In descriptions below, the mesh member 21 as an upper layer out of the two laminated mesh members 21 and 22 will be referred to as upper-layer mesh member 21, whereas the mesh member 22 as a lower layer out of those two members will be referred to as lower-layer mesh member 22.

The heat-transporting device 10 includes a vapor-phase flow path 11 that causes a working fluid in a vapor phase to circulate, a liquid-phase flow path 13 that causes the working fluid in a liquid phase to circulate, and an intermediate layer 12 interposed between the vapor-phase flow path 11 and the liquid-phase flow path 13.

The vapor-phase flow path 11 is formed by a cavity formed on the upper portion 1a side of the vessel 1. The liquid-phase flow path 13 is constituted of the lower-layer mesh member 22. The intermediate layer 12 is constituted of the upper-layer mesh member 21.

The intermediate layer 12 constituted of the upper-layer mesh member 21 has both the function as the vapor-phase flow path 11 that causes the vapor-phase working fluid to circulate and the function as the liquid-phase flow path 13 that causes the liquid-phase working fluid to circulate.

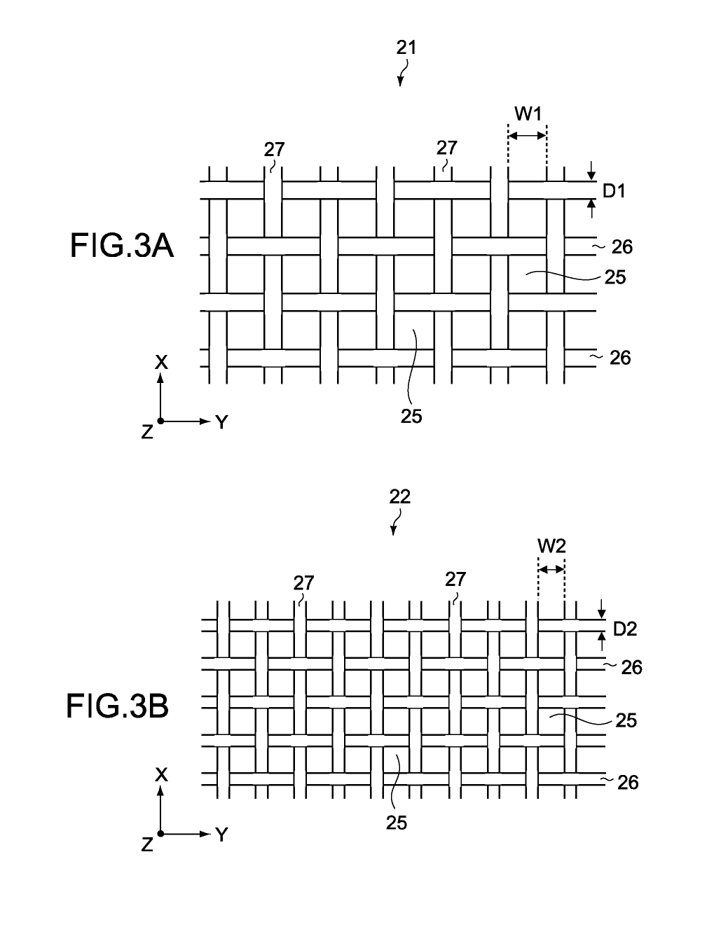

FIG. 3 are enlarged plan views of the upper-layer mesh member and the lower-layer mesh member, respectively. FIG. 3A is an enlarged plan view of the upper-layer mesh member 21, and FIG. 3B is an enlarged plan view of the lower-layer mesh member 22.

As shown in FIG. 3, the upper-layer mesh member 21 and the lower-layer mesh member 22 each include a plurality of first wires 26 that extend in the y-axis direction (flow-path direction) and a plurality of second wires 27 that extend in the x-axis direction (direction orthogonal to flow-path direction). The upper-layer mesh member 21 and the lower-layer mesh member 22 are each formed by weaving the plurality of first wires 26 and the plurality of second wires 27 in mutually-orthogonal directions.

As a way to weave the wires to obtain the upper-layer mesh member 21 and the lower-layer mesh member 22, there are, for example, plain weave and twilling. However, the present invention is not limited thereto, and lock crimp weave, flat-top weave, or other weaving methods may also be used.

A plurality of holes 25 are formed by spaces defined by the first wires 26 and the second wires 27. In the specification, holes formed by wires like the holes 25 may be referred to as meshes. In addition, intervals among the first wires 26 and intervals among the second wires 27 may each be referred to as open stitch, and a diameter of each of the first wires 26 and a diameter of each of the second wires 27 may be referred to as wire diameter.

For the upper-layer mesh member 21, a mesh member having rougher meshes than the lower-layer mesh member 22 is used. Typically, a mesh number of the upper-layer mesh member 21 is smaller than a mesh number of the lower-layer mesh member 22. The “mesh number” used herein refers to the number of meshes of the mesh member per inch (25.4 mm).

In descriptions below, in a case where a mesh number of a mesh member is abc, that mesh number may be represented as #abc. For example, the mesh number 100 is represented as #100.

For example, in a case where the mesh number of the upper-layer mesh member 21 is #100 and that of the lower-layer mesh member 22 is #200, an open stitch W1 of the upper-layer mesh member 21 is 170 μm (W1=170 μm) and a wire diameter D1 of a mesh is 80 μm (D1=80 μm), for example. Also in this case, an open stitch W2 of the lower-layer mesh member 22 is 85 μm (W2=85 μm) and a wire diameter D2 of a mesh is 45 μm (D2=45 μm), for example.

The combination of mesh numbers is not limited to the above combination. For example, the mesh number of the upper-layer mesh member 21 may be set to #150 and that of the lower-layer mesh member 22 may be set to #200. Regarding the combination of mesh numbers, the mesh number of the upper-layer mesh member 21 only needs to be smaller than the mesh number of the lower-layer mesh member 22, and the combination can be changed as appropriate.

Next, capillary radiuses of the vapor-phase flow path 11, the intermediate layer 12, and the liquid-phase flow path 13 will be described.

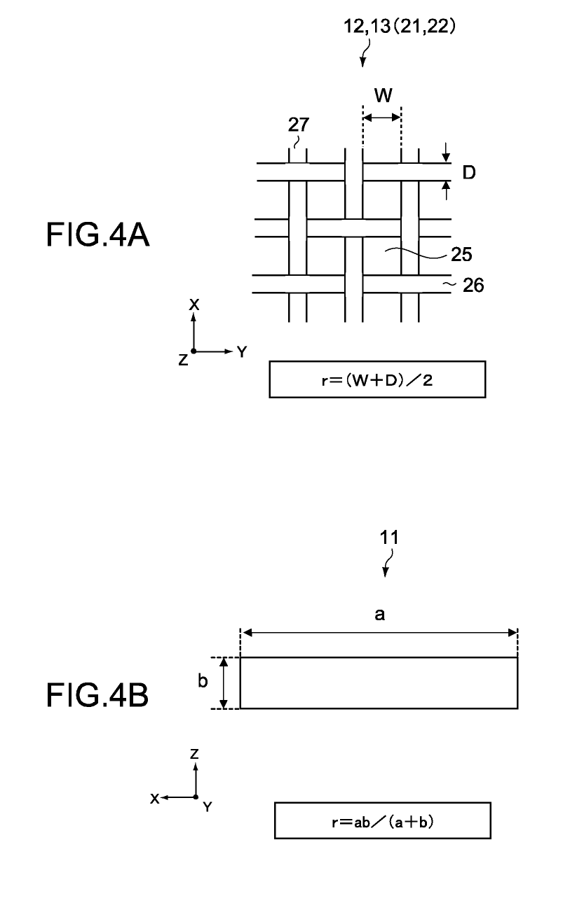

FIG. 4 are diagrams for explaining a capillary radius. FIG. 4A is a diagram for explaining a capillary radius in a case where a flow path of a working fluid is constituted of a mesh member. FIG. 4B is a diagram for explaining a capillary radius in a case where the flow path of the working fluid is a rectangular flow path.

As shown in FIG. 4A, when the flow path of the working fluid is constituted of a mesh member like the intermediate layer 12 and the liquid-phase flow path 13, a capillary radius r is expressed by Equation (1) below. It should be noted that in Equation (1), an open stitch of meshes is represented by W and a wire diameter of a mesh is represented by D.

r=(W+D)/2 (1)

On the other hand, when the flow path of the working fluid is constituted of a rectangular flow path like the vapor-phase flow path 11 as shown in FIG. 4B, the capillary radius r is expressed by Equation (2) below. It should be noted that in Equation (2), a width of the flow path is represented by a and a depth of the flow path is represented by b.

r=ab/(a+b) (2)

For example, when the open stitch W2 of meshes of the lower-layer mesh member 22 that constitutes the liquid-phase flow path 13 is 85 μm and the wire diameter Dl of a mesh thereof is 45 μm, the capillary radius of the liquid-phase flow path 13 becomes 65 μm based on Equation (1) above.

When the open stitch W1 of meshes of the upper-layer mesh member 21 that constitutes the intermediate layer 12 is 170 μm and the wire diameter Dl of a mesh thereof is 80 μm, the capillary radius of the intermediate layer 12 becomes 125 μm based on Equation (1) above.

When the width a of the vapor-phase flow path 11 is 30 mm and the depth b of the vapor-phase flow path 11 is 1 mm, the capillary radius of the vapor-phase flow path 11 becomes about 0.97 mm based on Equation (2) above.

Therefore, in the heat-transporting device 10 of this embodiment, the capillary radius r increases stepwise in the stated order of the liquid-phase flow path 13, the intermediate layer 12, and the vapor-phase flow path 11. Focusing on the capillary radius of the intermediate layer 12, the capillary radius of the intermediate layer 12 is larger than that of the liquid-phase flow path 13 but smaller than that of the vapor-phase flow path 11.

Next, a reason why the intermediate layer 12 is provided in the heat-transporting device 10 will be described. In other words, a reason why an intermediate layer that has a capillary radius larger than that of the liquid-phase flow path 13 but smaller than that of the vapor-phase flow path 11 is interposed between the vapor-phase flow path 11 and the liquid-phase flow path 13 will be described.

For describing the reason, while taking a general heat-transporting device as an example, a relationship between a capillary radius and heat-transporting performance will be described.

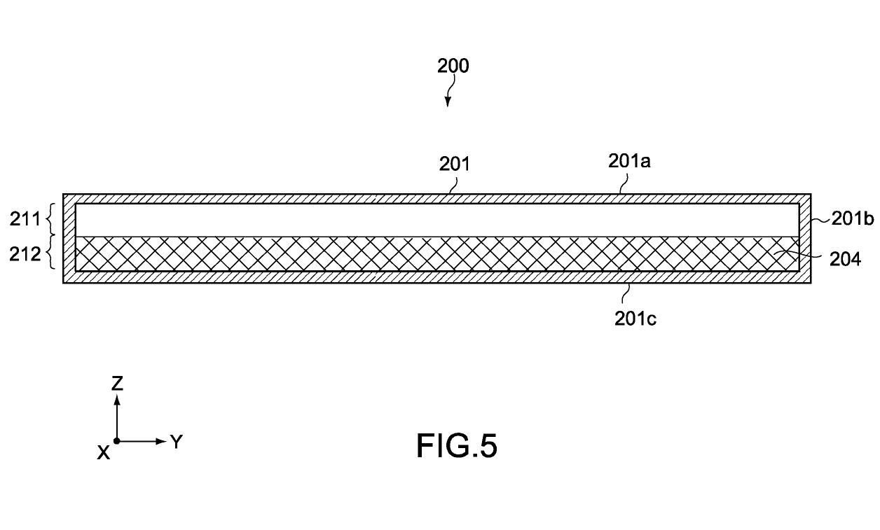

FIG. 5 is a cross-sectional side view of a general heat-transporting device.

As shown in FIG. 5, a heat-transporting device 200 includes a vessel 201. The vessel 201 is hollow on an upper portion 201a side, and a wick 204 is disposed on a lower portion 201c side thereof. For the wick 204, for example, a mesh member, felt, a metal form, a thin line, a sintered body, or a microchannel including fine grooves is used.

A vapor-phase flow path 211 that causes a vapor-phase working fluid to circulate is formed by the cavity formed on the upper portion 201a side of the vessel 201. Moreover, a liquid-phase flow path 212 that causes a liquid-phase working fluid to circulate is formed by the wick 204 disposed on the lower portion 201c side of the vessel 201.

Next, a typical operation of the general heat-transporting device will be described.

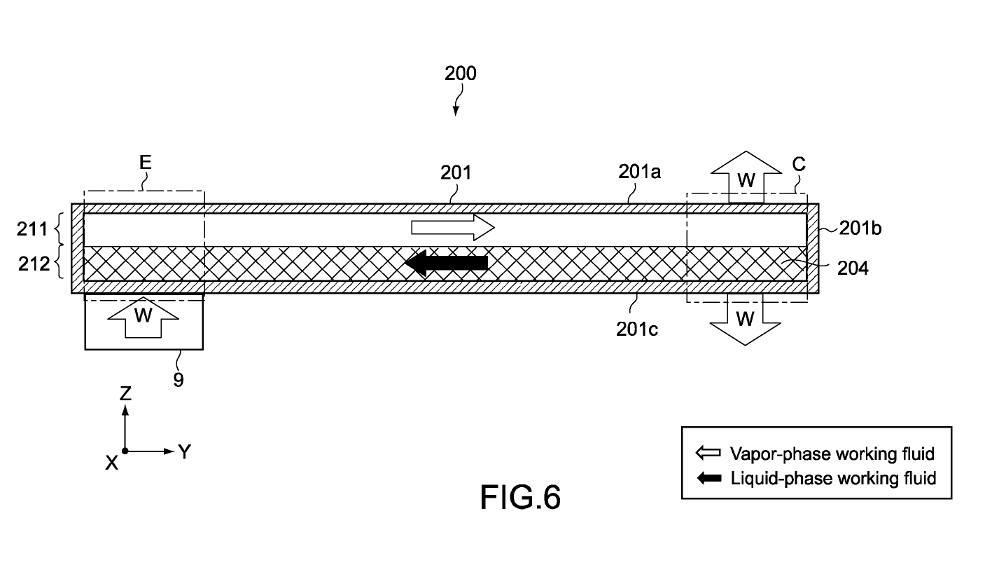

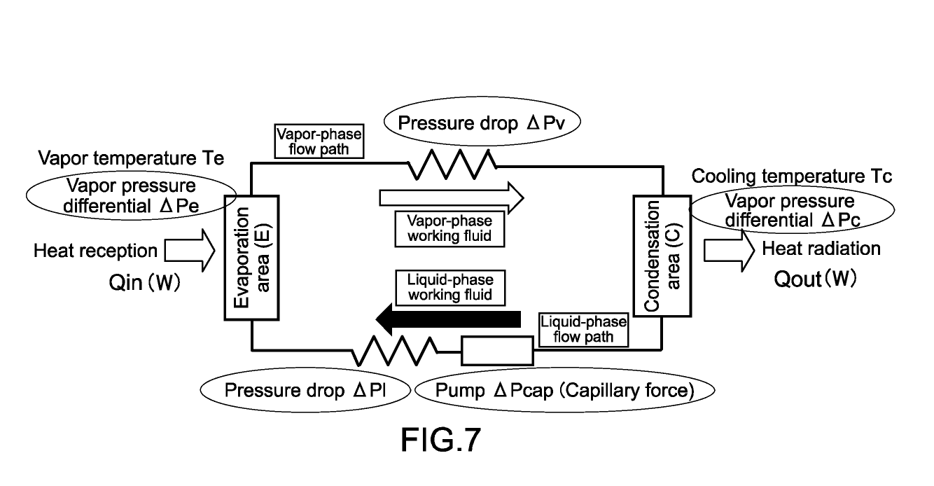

FIG. 6 is a schematic diagram for explaining an operation of the general heat-transporting device. Further, FIG. 7 is a cooling model diagram of the general heat-transporting device.

As shown in the figures, the heat-transporting device 200 is in contact with, at one end portion thereof on the lower portion 201c side, a heat source 9 such as a CPU, for example. The heat-transporting device 200 includes an evaporation area E at an end portion thereof on a side that is in contact with the heat source 9 and a condensation area C at the other end portion thereof.

Receiving heat from the heat source 9, the liquid-phase working fluid evaporates by a vapor pressure differential ΔPe to thus become a vapor-phase working fluid in the evaporation area E. The vapor-phase working fluid moves from the evaporation area E to the condensation area C via the vapor-phase flow path 211. At this time, the vapor-phase working fluid moves to the condensation area C while receiving a pressure drop ΔPv due to a vapor-phase resistance of the vapor-phase flow path 211.

The vapor-phase working fluid that has moved to the condensation area C radiates the heat W and is then condensed, and a phase thereof is changed so that the vapor-phase working fluid becomes the liquid-phase working fluid. The vapor pressure differential at this time is represented by ΔPc. The liquid-phase working fluid flows through the liquid-phase flow path with a capillary force ΔPcap of the wick 204 as a pumping force and thus moves to the evaporation area E from the condensation area C. At this time, the liquid-phase working fluid moves to the evaporation area E while receiving a liquid-phase resistance ΔPl of the liquid-phase flow path 212.

The liquid-phase working fluid that has returned to the evaporation area E again receives heat from the heat source 9 and evaporates. By repeating the above operation, heat from the heat source 9 is transported.

When a total pressure drop of the heat-transporting device 200 is smaller than the capillary force ΔPcap of the wick 204, the heat-transporting device 200 operates. Conversely, when the total pressure drop is larger than the capillary force ΔPcap of the wick 204, the heat-transporting device 200 does not operate. A maximum heat-transporting amount Qmax of the heat-transporting device 200 can be obtained when the total pressure drop and the capillary force are balanced.

Therefore, ΔPcap with which the maximum heat-transporting amount Qmax can be obtained is expressed by Equation (3) below. It should be noted that in Equation (3), a pressure drop of the vapor-phase working fluid is represented by ΔPv, a pressure drop of the liquid-phase working fluid is represented by ΔPl, a pressure differential due to evaporation is represented by ΔPe, a pressure differential due to condensation is represented by ΔPc, and a pressure differential due to a volume force is represented by ΔPh.

ΔAPcap=ΔPv+AP1+ΔPe+ΔPc+ΔΔPh (3)

Here, assuming that a flow-path resistance per unit heat quantity is represented by Rq, the maximum heat-transporting amount Qmax can be expressed by Equation (4) below.

Qmax=ΔPcap/Rq (4)

Moreover, assuming that latent heat is represented by H and a total flow-path resistance is represented by Rtotal, the maximum heat-transporting amount Qmax can be expressed by Equation (5) below.

Qmax=ΔPcap*H/Rtotal (5)

The total flow-path resistance Rtotal is a sum of a vapor-phase resistance Rv, a liquid-phase resistance R1, a boiling resistance Re, a condensation resistance Rc, and a resistance due to a volume force Rb. Therefore, in general, the maximum heat-transporting amount Qmax increases as the capillary force ΔPcap increases and decreases as the liquid-phase resistance R1 increases.

The pressure drop ΔPv of the vapor-phase working fluid, the pressure drop ΔPl of the liquid-phase working fluid, the pressure differential ΔPe due to evaporation, the pressure differential ΔPc due to condensation, and the pressure differential ΔPh due to the volume force Rb can be respectively expressed by Equations (6) to (10) below. In Equations (6) to (10), a viscosity coefficient of the vapor-phase working fluid is represented by μv, a viscosity coefficient of the liquid-phase working fluid is represented by μl, a density of the vapor-phase working fluid is represented by ρv, and a density of the liquid-phase working fluid is represented by ρl. Moreover, a heat-transporting amount is represented by Q, a length of the heat-transporting device 200 is represented by L, a length of the evaporation area E is represented by le, a length of the condensation area C is represented by lc, a cross-sectional area of the wick 204 is represented by Aw, and a capillary radius of the vapor-phase flow path 211 is represented by rv. In addition, an infiltration coefficient is represented by K, a vapor constant is represented by R, a gravity acceleration is represented by g, and a tilt of the heat-transporting device 200 with respect to a horizontal direction is represented by φ. It should be noted that the volume force Rb becomes 0 at a time the heat-transporting device 200 is used horizontally.

ΔPv=8*μv*Q*L/(n*ρv*rv̂4*H) (6)

ΔPl=μl*Q*L/(K*Aw*ρl*H) (7)

ΔPe=(RT/2π)̂(½)*Q/[αc(H−½*RT)*rv*le] (8)

ΔPc=(RT/2π)̂(½)*Q/[αc(H−½*RT)*rv*lc] (9)

ΔPh=(ρl−ρv)*g*L*sin φ (10)

Focusing on Equations (6), (8), and (9) out of Equations (6) to (10) above, it can be seen that the pressure drop ΔPv of the vapor-phase working fluid, the pressure differential ΔPe due to evaporation, and the pressure differential ΔPc due to condensation are functions of the capillary radius rv of the vapor-phase flow path 211. The capillary radius rv of the vapor-phase flow path 211 is used as a denominator in all of Equations (6), (8), and (9). Therefore, it can be seen that it is possible to reduce the three pressure drops ΔPv, ΔPe, and ΔPc and increase the maximum heat-transporting amount Qmax by widening the capillary radius rv of the vapor-phase flow path 211.

Here, in a case where the vapor-phase flow path 211 and the liquid-phase flow path 212 are in contact with each other in the heat-transporting device 200 as shown in FIG. 6, both the liquid-phase working fluid and the vapor-phase working fluid are present in the liquid-phase flow path 212 in an area where it comes into contact with the vapor-phase flow path 211. Therefore, a clear distinction cannot be made between the vapor-phase flow path 211 and the liquid-phase flow path 212, and that area functions as both the liquid-phase flow path 212 and the vapor-phase flow path 211. In actuality, the capillary radius rv of the vapor-phase flow path 211 is also affected by that area.

In this regard, in the heat-transporting device 10 of this embodiment, the intermediate layer 12 is interposed between the vapor-phase flow path 11 and the liquid-phase flow path 13. Specifically, in this embodiment, for practically widening the capillary radius rv of the vapor-phase flow path 11, the intermediate layer 12 is provided especially as a dedicated area that has both the function as the vapor-phase flow path 11 and the function as the liquid-phase flow path 13.

The capillary radius of the intermediate layer 12 is set to be larger than the capillary radius of the liquid-phase flow path 13 but smaller than the capillary radius of the vapor-phase flow path 11 as described above. As a result, the capillary radius rv of the vapor-phase flow path can be widened appropriately.

Accordingly, since the pressure drop ΔPv of the vapor-phase working fluid, the pressure differential ΔPe due to evaporation, and the pressure differential ΔPc due to condensation can be suppressed, the maximum heat-transporting amount Qmax of the heat-transporting device 10 can be increased. As a result, the heat-transporting performance of the heat-transporting device 10 can be improved.

(Description on Operation)

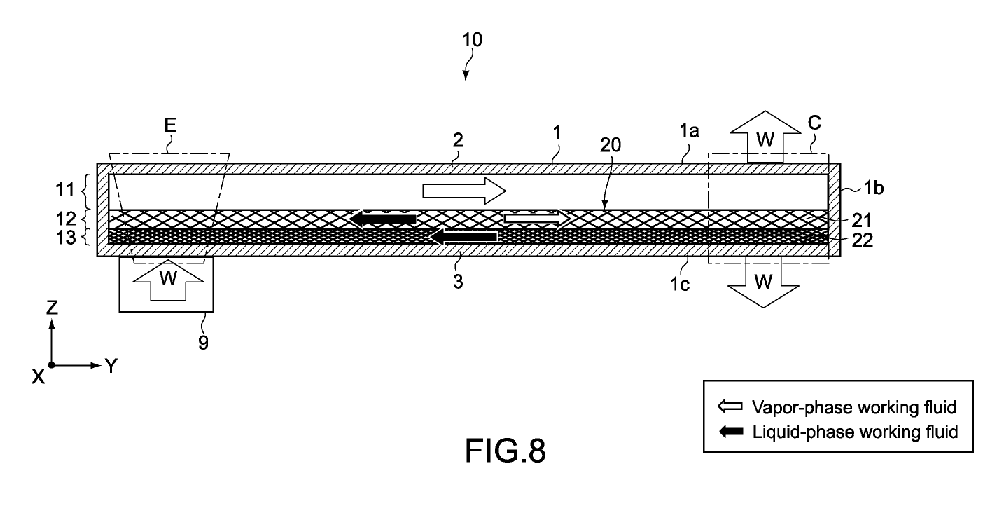

Next, an operation of the heat-transporting device 10 will be described. FIG. 8 is a schematic diagram for explaining the operation of the heat-transporting device. In FIG. 8, points different from those of the operation described with reference to FIGS. 6 and 7 will mainly be described.

As shown in FIG. 8, the heat-transporting device 10 is in contact with, at one end portion thereof on the lower portion 1c side, the heat source 9 such as a CPU. The heat-transporting device 10 includes the evaporation area E at an end portion thereof on a side that is in contact with the heat source 9 and the condensation area C at the other end portion thereof.

The liquid-phase working fluid absorbs heat W from the heat source 9 and evaporates by the vapor pressure differential ΔPe in the evaporation area E. At this time, since the capillary radius rv of the vapor-phase flow path 11 is practically widened by the intermediate layer 12 as described above, the pressure differential ΔPe due to evaporation is reduced (see Equation (8)). Therefore, it is possible for the liquid-phase working fluid to evaporate with a low boiling resistance.

The working fluid that has evaporated (vapor-phase working fluid) moves toward the condensation area C from the evaporation area E. At this time, the vapor-phase working fluid moves to the condensation area C via the vapor-phase flow path 11 and the intermediate layer 12. In other words, the vapor-phase working fluid passes not only the vapor-phase flow path 11 but also the intermediate layer 12 constituted of the upper-layer mesh member 21, to thus move to the condensation area C.

At this time, since the pressure drop ΔPv of the vapor-phase working fluid is reduced by the intermediate layer 12 (see Equation (6)), the vapor-phase working fluid is capable of moving to the condensation area C with a low flow-path resistance. Because the pressure drop ΔPv of the vapor-phase working fluid is inversely proportional to a quadruplicate of the capillary radius rv of the vapor-phase flow path 11, an effect of reducing the pressure drop ΔPv by widening the capillary radius rv is particularly large.

The vapor-phase working fluid that has reached the condensation area C radiates the heat W and is condensed by the vapor pressure differential ΔPc. At this time, since the pressure differential ΔPc due to condensation is reduced by the intermediate layer 12 (see Equation (9)), the vapor-phase working fluid can be condensed with a low condensation resistance.

The condensed working fluid (liquid-phase working fluid) moves from the condensation area C to the evaporation area E via the liquid-phase flow path 13 constituted of the lower-layer mesh member 22 and the intermediate layer 12 constituted of the upper-layer mesh member 21. The liquid-phase working fluid that has returned to the evaporation area E again receives heat from the heat source 9 and evaporates. By repeating the operation above, heat from the heat source 9 is transported.

As described above, in the heat-transporting device 10 of this embodiment, the pressure drop ΔPv of the vapor-phase working fluid, the pressure differential ΔPe due to evaporation, and the pressure differential ΔPc due to condensation can be reduced. Accordingly, since a total pressure drop Ptotal can be reduced, the maximum heat-transporting amount Qmax of the heat-transporting device 10 can be increased. As a result, the heat-transporting performance of the heat-transporting device 10 can be improved.

Here, in FIG. 8, the heat source 9 is in contact with the lower portion 1c side, that is, the liquid-phase flow path 13 side of the heat-transporting device 10. Further, as described above, the mesh numbers decrease stepwise from the lower-layer mesh member 22 to the upper-layer mesh member 21, and meshes gradually become rougher from the lower portion 1c side. In this case, the meshes gradually become rougher from the lower portion 1c side that is in contact with the heat source 9 to the upper portion 1a side on which the vapor-phase flow path 11 is provided. Accordingly, since it is possible to gradually widen the evaporation area E from the lower portion 1c side of the heat-transporting device 10 to the upper portion 1a side thereof as shown in FIG. 8, boiling efficiency of the liquid-phase working fluid can be improved. Furthermore, since the lower-layer mesh member 22 side of the heat-transporting device 10 that has finer meshes is in contact with the heat source 9, heat conductivity can also be improved.

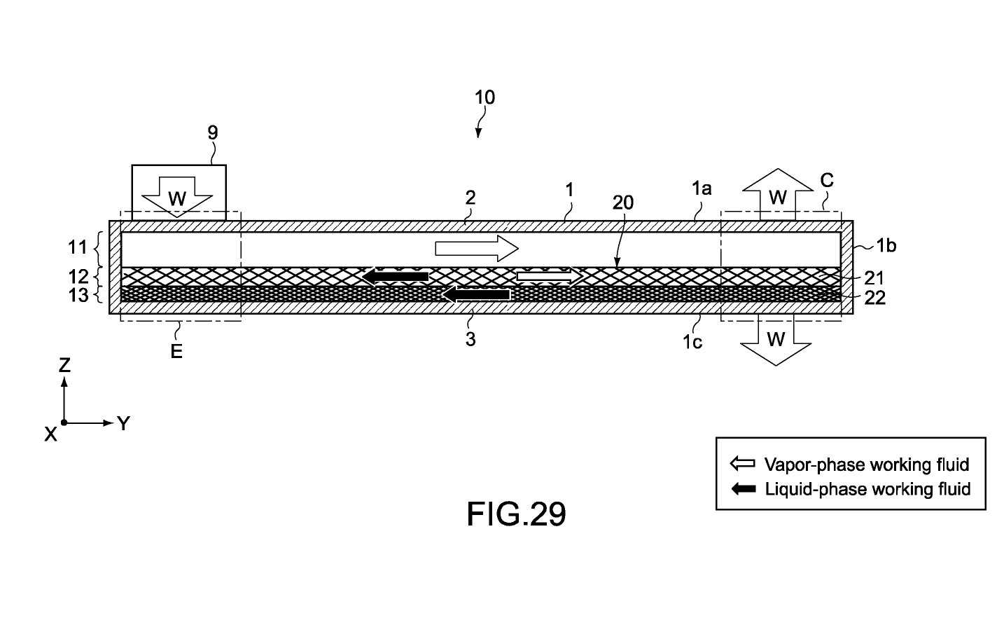

However, the heat source 9 does not always need to be provided on the lower portion 1c side of the heat-transporting device 10. For example, since a temperature difference between the lower portion 1c side and the upper portion 1a side becomes small when the thickness T of the heat-transporting device 10 is small (e.g., about 3 mm or less), the pressure differential ΔPe due to evaporation is reduced. Thus, in this case, it is also possible to provide the heat source 9 on the upper portion 1a side of the heat-transporting device 10 (vapor-phase flow path 11 side). It should be noted that for reference, the heat-transporting device 10 in which the heat source 9 is disposed on the vapor-phase flow path 11 side is shown in FIG. 29.

(Evaluation on Heat-Transporting Performance)

Next, heat-transporting performance of the heat-transporting device 10 will be described in more detail.

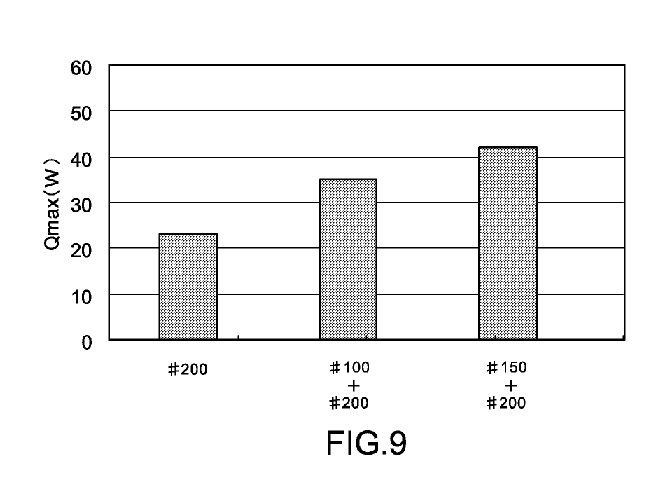

FIG. 9 is a diagram for explaining heat-transporting performance of a heat-transporting device, the diagram showing a maximum heat-transporting amount Qmax of a heat-transporting device including an intermediate layer and a heat-transporting device that does not include the intermediate layer.

For evaluating the heat-transporting performance of the heat-transporting device 10, the inventors of the present invention prepared a heat-transporting device 10 including the intermediate layer 12 and a heat-transporting device 200 that does not include the intermediate layer 12 and compared the heat-transporting performance of those heat-transporting devices.

As the heat-transporting device 10 including the intermediate layer 12, a heat-transporting device 10 including mesh members 22 and 21 whose mesh numbers are #200 and #100, respectively, from the lower layer and a heat-transporting device 10 including mesh members 22 and 21 whose mesh numbers are #200 and #150, respectively, from the lower layer were used. On the other hand, as the heat-transporting device 200 that does not include the intermediate layer 12, a heat-transporting device 200 including a mesh member 204 whose mesh number is #200 was used. The heat-transporting device 200 that does not include the intermediate layer 12 includes the mesh member 204 of only a single layer (see FIG. 5). The heat-transporting performance is evaluated by comparing the maximum heat-transporting amounts Qmax of the heat transporting devices 10 and 200.

In the mesh member whose mesh number is #100, the open stitch W of meshes is set to 170 μm, and the wire diameter D is set to 80 μm. In the mesh member whose mesh number is #150, the open stitch W of meshes is set to 105 μm, and the wire diameter D is set to 65 μm. In the mesh member whose mesh number is #200, the open stitch W of meshes is set to 85 μm, and the wire diameter D is set to 45 μm. In this case, the capillary radius r increases stepwise in the stated order of the liquid-phase flow path 13, the intermediate layer 12, and the vapor-phase flow path 11 (see FIG. 4).

As shown in FIG. 9, the maximum heat-transporting amount Qmax of the heat-transporting device 10 including the intermediate layer 12 (center and right-hand graphs) is dramatically increased as compared to that of the heat-transporting device 200 that does not include the intermediate layer 12 (left-hand graph). As a result, it can be seen that the heat-transporting performance of the heat-transporting device 10 including the intermediate layer 12 is dramatically improved.

The reason why such a result is obtained is because, as described above, the capillary radius rv of the vapor-phase flow path 11 can be practically widened by the intermediate layer 12. When the capillary radius rv of the vapor-phase flow path 11 is practically widened, the maximum heat-transporting amount Qmax increases and the heat-transporting performance is improved as described above.

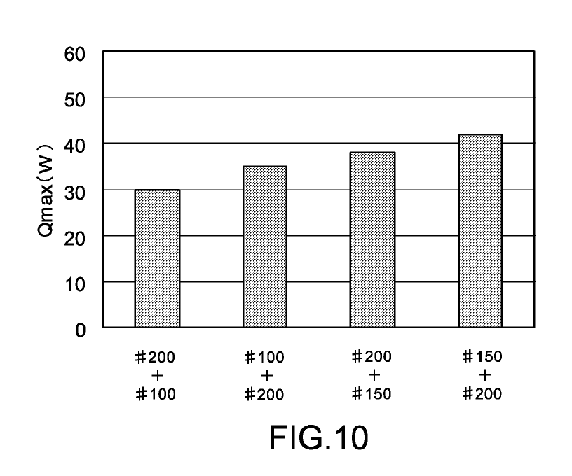

FIG. 10 is a diagram obtained as a result of comparing a maximum heat-transporting amount Qmax in a case where the mesh numbers increase stepwise from the lower layer and a maximum heat-transporting amount Qmax in a case where the mesh numbers decrease stepwise from the lower layer.

In FIG. 10, a structure in which the mesh number of the upper-layer mesh member 21 is larger than the mesh number of the lower-layer mesh member 22 and a structure in which the mesh number of the upper-layer mesh member 21 is smaller than the mesh number of the lower-layer mesh member 22 were used. In other words, a structure in which meshes of the intermediate layer 12 are finer than those of the liquid-phase flow path 13 and a structure in which the meshes of the intermediate layer 12 are rougher than those of the liquid-phase flow path 13 were used.

It can be seen from FIG. 10 that the maximum heat-transporting amount Qmax is larger in a case where the mesh number of the upper-layer mesh member 21 is smaller than that of the lower-layer mesh member 22 than in a case where the mesh number of the upper-layer mesh member 21 is larger than that of the lower-layer mesh member 22.

For example, focusing on the smallest graph and the second from the smallest in FIG. 10, the maximum heat-transporting amount Qmax is larger in a case where the mesh members are laminated such that mesh numbers sequentially become #200 and #100 from the lower layer than in a case where the mesh members are laminated such that mesh numbers sequentially become #100 and #200 from the lower layer.

Similarly, focusing on the largest graph and the second from the largest in FIG. 10, the maximum heat-transporting amount Qmax is larger in a case where the mesh members are laminated such that mesh numbers sequentially become #200 and #150 from the lower layer than in a case where the mesh members are laminated such that mesh numbers sequentially become #150 and #200 from the lower layer.

In other words, even when the mesh members 21 and 22 having the same mesh number are used, the heat-transporting performance is improved more when a mesh member having rougher meshes than the liquid-phase flow path 13 is used for the intermediate layer 12.

The reason why such a result is obtained is because, by forming the intermediate layer 12 having rougher meshes than the liquid-phase flow path 13, the practical capillary radius rv of the vapor-phase flow path 11 can be widened efficiently.

### Second Embodiment

Next, a second embodiment of the present invention will be described.

The first embodiment above has described a case where the intermediate layer 12 and the liquid-phase flow path 13 are constituted of two mesh members 21 and 22. In the second embodiment, however, the intermediate layer 12 and the liquid-phase flow path 13 are constituted of three mesh members 31 to 33. Therefore, that point will mainly be described.

It should be noted that in descriptions below, components having the same structures and functions as those of the first embodiment above are denoted by the same reference symbols, and descriptions thereof will be omitted or simplified.

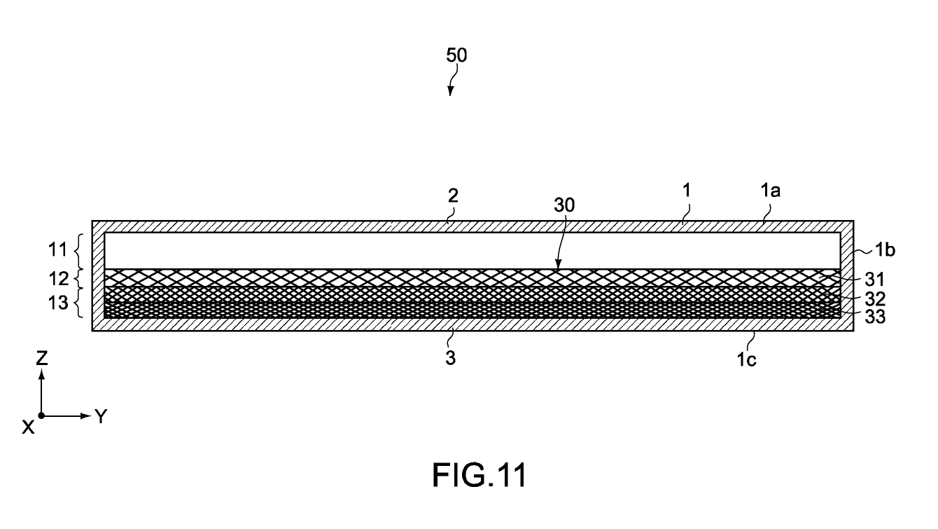

FIG. 11 is a cross-sectional side view of a heat-transporting device according to the second embodiment.

As shown in FIG. 11, a heat-transporting device 50 of the second embodiment includes a laminated body 30 that has three mesh members 31 to 33. The laminated body 30 is provided on the lower portion 1c side of the heat-transporting device 50.

In descriptions below, out of the three mesh members, the mesh member 31 as an upper layer will be referred to as upper-layer mesh member 31, the mesh member 32 as an intermediate layer will be referred to as intermediate-layer mesh member 32, and the mesh member 33 as a lower layer will be referred to as lower-layer mesh member 33.

The vapor-phase flow path 11 is constituted of a cavity formed on the upper portion 1a side, and the intermediate layer 12 is constituted of the upper-layer mesh member 31. Moreover, the liquid-phase flow path 13 is constituted of the intermediate-layer mesh member 32 and the lower-layer mesh member 33. In other words, in the second embodiment, the liquid-phase flow path 13 is constituted of two mesh members 32 and 33.

The mesh members 31 to 33 are laminated so that mesh numbers thereof decrease stepwise from the lower layer. In other words, the mesh members are laminated such that meshes thereof gradually become rougher from the lower layer. It should be noted that in this case, the capillary radiuses increase stepwise in the stated order of the liquid-phase flow path 13, the intermediate layer 12, and the vapor-phase flow path 11 (see FIG. 4).

For example, the mesh number of the lower-layer mesh member 33 is set to #200, the mesh number of the intermediate-layer mesh member 32 is set to #150, and the mesh number of the upper-layer mesh member 31 is set to #100.

However, the combination of mesh numbers is not limited to that described above. For example, the mesh number of the lower-layer mesh member 33 may be set to #300, the mesh number of the intermediate-layer mesh member 32 may be set to #200, and the mesh number of the upper-layer mesh member 31 may be set to #150. The mesh numbers only need to decrease stepwise from the lower layer, and the combination of mesh numbers can be changed as appropriate.

Even when the liquid-phase flow path 13 is constituted of two mesh members, the second embodiment bears the same effect as the first embodiment above. Specifically, since the intermediate layer 12 is constituted of the upper-layer mesh member 31 and the practical capillary radius rv of the vapor-phase flow path 11 can thus be widened, the heat-transporting performance of the heat-transporting device 50 can be improved.

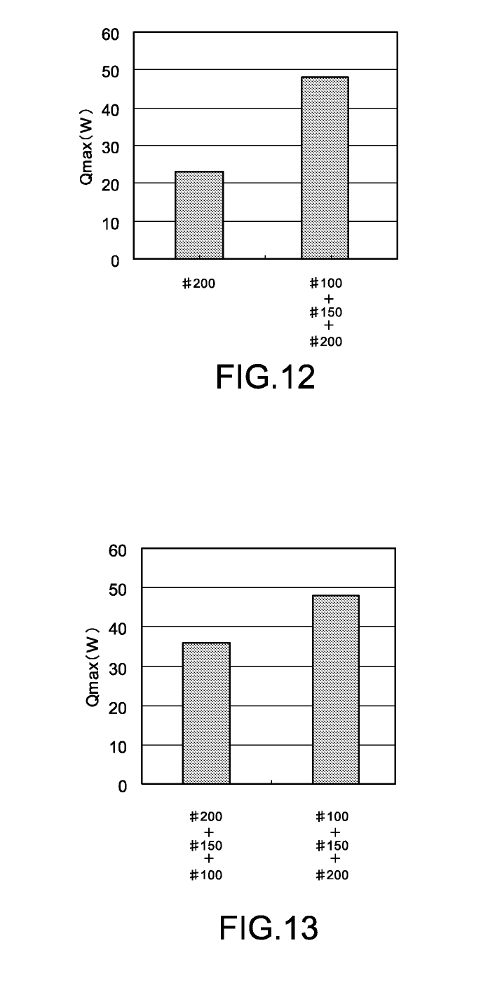

FIG. 12 is a diagram showing a maximum heat-transporting amount Qmax of the heat-transporting device according to the second embodiment and the heat-transporting device that does not include the intermediate layer.

For the heat-transporting device 200 that does not include the intermediate layer 12, a heat-transporting device 200 that includes a mesh member 204 of #200 was used. The heat-transporting device 200 that does not include the intermediate layer 12 includes the mesh member 204 of only a single layer (see FIG. 5).

As shown in FIG. 12, the maximum heat-transporting amount Qmax is dramatically increased in the heat-transporting device 50 according to the second embodiment as compared to the heat-transporting device 200 that does not include the intermediate layer 12. It is substantiated from FIG. 12 that the heat-transporting performance of the heat-transporting device that includes the intermediate layer 12 is improved.

FIG. 13 is a diagram obtained as a result of comparing a maximum heat-transporting amount Qmax in a case where the mesh numbers increase stepwise from the lower layer and a maximum heat-transporting amount Qmax in a case where the mesh numbers decrease stepwise from the lower layer.

As shown in FIG. 13, it can be seen that the maximum heat-transporting amount Qmax is larger in a case where the mesh numbers decrease stepwise from the lower layer than in a case where the mesh numbers increase stepwise from the lower layer.

The description on FIG. 11 has been given on a case where the laminated body 30 is constituted of three mesh members 31 to 33 and the liquid-phase flow path 13 is constituted of two mesh members 32 and 33. However, the present invention is not limited thereto, and the liquid-phase flow path 13 may be constituted of three or more mesh members. In this case, a plurality of mesh members that constitute the liquid-phase flow path 13 are laminated such that mesh numbers thereof decrease stepwise from the lower layer.

### Third Embodiment

Next, a third embodiment of the present invention will be described.

The description on the second embodiment above has been given assuming that the mesh numbers of the mesh members 31 to 33 decrease stepwise from the lower layer. In the third embodiment, however, the mesh numbers of the mesh members 31 to 33 except that of the lower-layer mesh member 33 decrease stepwise from the lower layer. Therefore, that point will mainly be described.

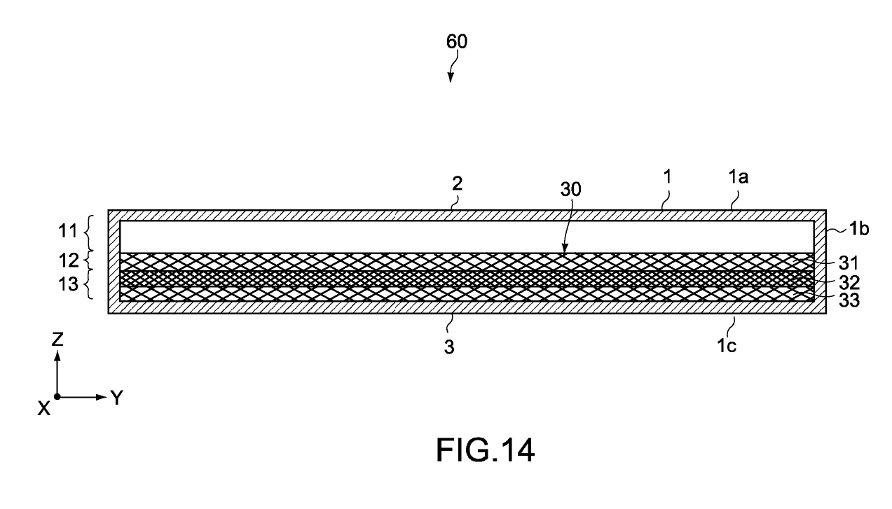

FIG. 14 is a cross-sectional side view of a heat-transporting device according to the third embodiment.

As shown in FIG. 14, a heat-transporting device 60 includes the laminated body 30 on the lower portion 1c side thereof. The laminated body 30 includes the upper-layer mesh member 31 that constitutes the intermediate layer 12 and the intermediate-layer mesh member 32 and lower-layer mesh member 33 that constitute the liquid-phase flow path 13.

For example, the mesh number of the lower-layer mesh member 33 is set to #100, the mesh number of the intermediate-layer mesh member 32 is set to #150, and the mesh number of the upper-layer mesh member 31 is set to #100.

However, the combination of mesh numbers is not limited to that described above. For example, the mesh number of the lower-layer mesh member 33 may be set to #150, the mesh number of the intermediate-layer mesh member 32 may be set to #200, and the mesh number of the upper-layer mesh member 31 may be set to #150. The mesh numbers except the mesh number of the lower-layer mesh member 33 only need to decrease stepwise from the lower layer, and the combination of mesh numbers can be changed as appropriate.

Next, a reason why the mesh numbers except the mesh number of the lower-layer mesh member 33 decrease stepwise from the lower layer will be described. In other words, a reason why the lower-layer mesh member 33 is not given the largest mesh number (why meshes are not finest) will be described.

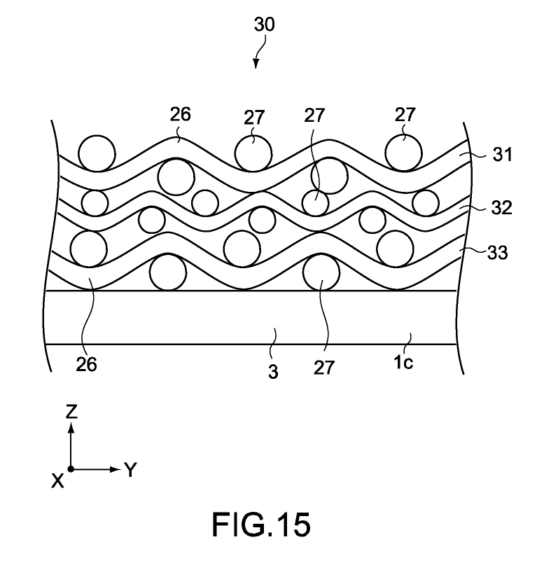

FIG. 15 is an enlarged cross-sectional diagram of the laminated body 30 for explaining the reason.

As shown in FIG. 15, the lower-layer mesh member 33 that is positioned at the very bottom of the laminated body 30 is in contact with the lower plate member 3 that constitutes the lower portion 1c of the heat-transporting device 60. Therefore, a space between the lower-layer mesh member 33 and the lower plate member 3 is smaller than spaces among the mesh members 31 to 33. Thus, the heat-transporting device can exert high heat-transporting performance even when the mesh number of the lower-layer mesh member 33 is not the largest.

In this regard, in the third embodiment, the mesh numbers except the mesh number of the lower-layer mesh member 33 decrease stepwise from the lower layer.

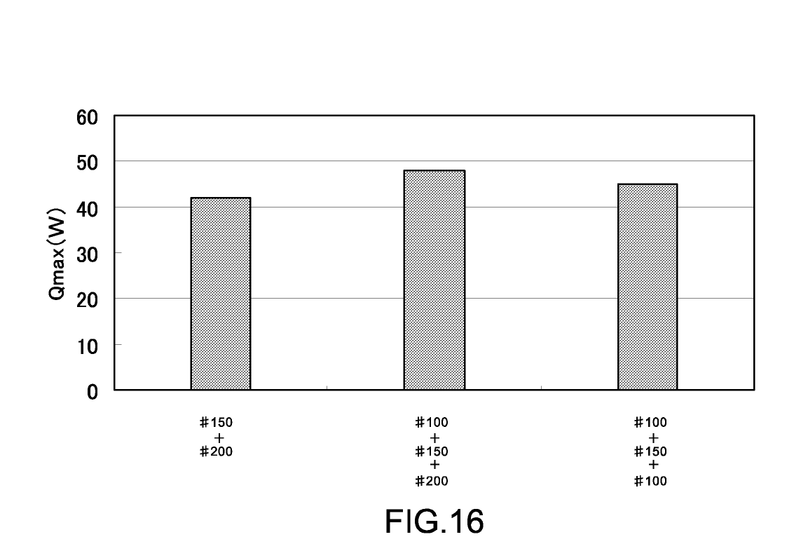

FIG. 16 is a diagram for explaining the heat-transporting performance of the heat-transporting device according to this embodiment.

In FIG. 16, the right-hand graph (#100+#150+#100) shows a maximum heat-transporting amount Qmax of the heat-transporting device 60 according to the third embodiment. The graph in the middle (#100+#150+#200) shows a maximum heat-transporting amount Qmax in a case where the mesh numbers decrease stepwise from the lower layer (second embodiment). Further, the left-hand graph (#150+#200) shows a maximum heat-transporting amount Qmax in a case where the laminated body 20 is constituted of two mesh members and the mesh numbers decrease stepwise from the lower layer (first embodiment).

It can be seen from FIG. 16 that the heat-transporting device according to the third embodiment also has high heat-transporting performance as in the first and second embodiments above. In other words, it can be seen that even when the mesh numbers except the mesh number of the lower-layer mesh member 33 decrease stepwise from the lower layer, high heat-transporting performance can be exerted.

The third embodiment has described a case where the laminated body 30 is constituted of three mesh members 31 to 33 and the liquid-phase flow path 13 is constituted of two mesh members 32 and 33. However, the present invention is not limited thereto, and the liquid-phase flow path 13 may be constituted of three or more mesh members. In this case, mesh numbers except a mesh number of a mesh member that is positioned at the very bottom out of a plurality of mesh members constituting the liquid-phase flow path 13 decrease stepwise from the lower layer.

### Fourth Embodiment

Next, a fourth embodiment of the present invention will be described.

The above embodiments have described cases where the vapor-phase flow path 11 is hollow. However, a heat-transporting device according to the fourth embodiment is provided with columnar portions 5 in the vapor-phase flow path 11. Therefore, that point will mainly be described.

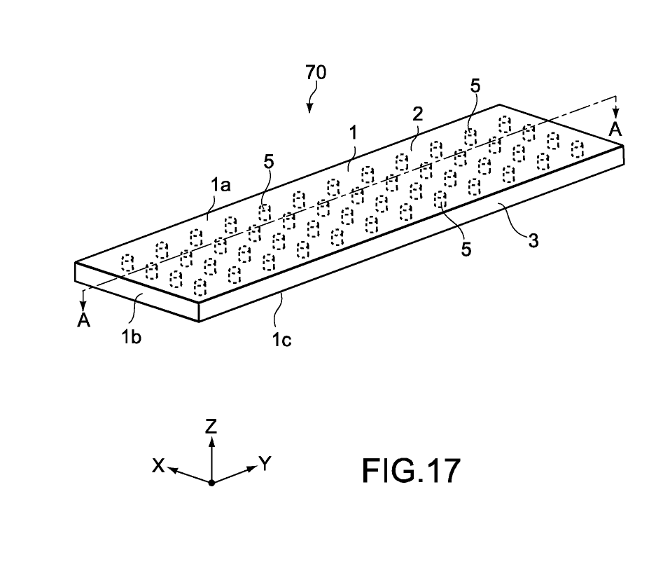

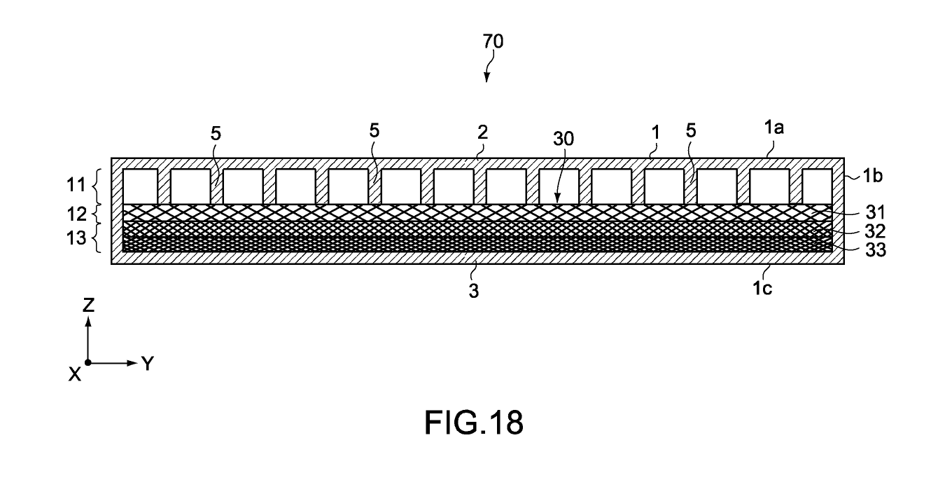

FIG. 17 is a perspective view of the heat-transporting device according to the fourth embodiment. FIG. 18 is a cross-sectional diagram taken along the line A-A of FIG. 17.

As shown in the figures, in a heat-transporting device 70, the vapor-phase flow path 11 is provided with a plurality of columnar portions 5. The plurality of columnar portions 5 are arranged in the x- and y-axis directions at predetermined intervals.

The columnar portions 5 are each formed to be cylindrical, though not limited thereto. The columnar portions 5 may each be a quadrangular prism or a polygonal column of a quadrangular prism or more. The shape of the columnar portions 5 is not particularly limited.

The columnar portions 5 are formed by partially etching the upper plate member 2, for example. The method of forming columnar portions 5 is not limited to etching. Examples of the method of forming columnar portions 5 include a metal-plating method, press work, and cutting work.

By forming the columnar portions 5 in the vapor-phase flow path 11 as shown in FIGS. 17 and 18, durability of the heat-transporting device can be enhanced. For example, it becomes possible to prevent the vessel 1 from being deformed due to a pressure at a time an internal temperature of the heat-transporting device 70 increases or a time a working fluid is injected into the heat-transporting device 70 in a reduced-pressure state. In addition, it is possible to enhance durability of the heat-transporting device 70 in a case where the heat-transporting device 70 is subjected to a bending process.

It should be noted that although the description on the fourth embodiment has been mainly given on the structure of the vapor-phase flow path 11, any of the structures described in the above embodiments is applicable to the intermediate layer 12 and the liquid-phase flow path 13. The same holds true for a fifth embodiment to be described below.

### Fifth Embodiment

Next, the fifth embodiment of the present invention will be described.

The fourth embodiment above has described a case where the columnar portions 5 are formed in the vapor-phase flow path 11. In the fifth embodiment, however, a mesh member 34 is provided in the vapor-phase flow path 11. Therefore, that point will mainly be described.

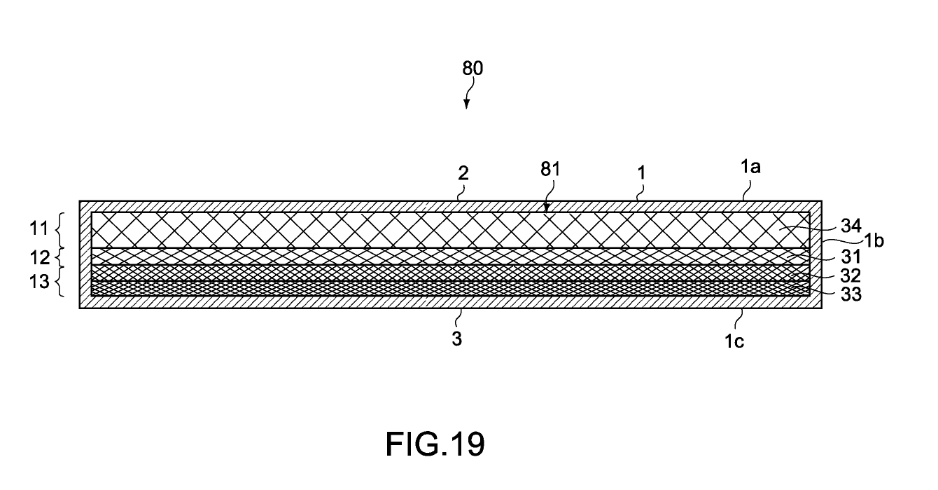

FIG. 19 is a cross-sectional side view of a heat-transporting device according to the fifth embodiment.

As shown in FIG. 19, a heat-transporting device 80 includes a laminated body 81 inside the vessel 1. The laminated body 81 includes the upper-layer mesh member 31 that constitutes the intermediate layer 12, the intermediate-layer mesh member 32 and the lower-layer mesh member 33 that constitute the liquid-phase flow path 13, and the mesh member 34 that constitutes the vapor-phase flow path 11. In descriptions below, the mesh member 34 that constitutes the vapor-phase flow path 11 will be referred to as vapor-phase mesh member 34.

The vapor-phase mesh member 34 is laminated on top of the upper-layer mesh member 31 to thus form a 4-layer laminated body 81.

The vapor-phase mesh member 34 has a mesh number that is smaller than the mesh number of the upper-layer mesh member 31. In other words, for the vapor-phase mesh member 34 that constitutes the vapor-phase flow path 11, a mesh member that has rougher meshes than the upper-layer mesh member 31 that constitutes the intermediate layer 12 is used. For example, the vapor-phase mesh member 34 has a mesh number that is about ⅓ to 1/20 the mesh number of the upper-layer mesh member 31, though not limited thereto.

As described above, the mesh numbers decrease in the stated order of the lower-layer mesh member 33, the intermediate-layer mesh member 32, and the upper-layer mesh member 31. Therefore, the mesh numbers including the mesh number of the vapor-phase mesh member 34 decrease stepwise from the lower layer. As a result, since meshes gradually become rougher in the stated order of the liquid-phase flow path 13, the intermediate layer 12, and the vapor-phase flow path 11, the heat-transporting performance of the heat-transporting device can be improved efficiently.

It should be noted that in this case, the capillary radius r increases stepwise in the stated order of the liquid-phase flow path 13, the intermediate layer 12, and the vapor-phase flow path 11 (see FIG. 4A).

Even when the vapor-phase flow path 11 is constituted of the vapor-phase mesh member 34 as in this embodiment, durability of the heat-transporting device 80 can be enhanced as in the fourth embodiment above. In addition, since all of the vapor-phase flow path 11, the intermediate layer 12, and the liquid-phase flow path 13 are constituted of a mesh member in the fifth embodiment, a structure is extremely simple. Therefore, it is possible to easily produce a heat-transporting device 80 that has high heat-transporting performance and high durability. Moreover, costs can also be reduced.

### Sixth Embodiment

Next, a sixth embodiment of the present invention will be described.

The above embodiments have been described assuming that the vessel 1 is constituted of two plate members 2 and 3. In the sixth embodiment, however, the vessel is formed by bending a single plate member. Therefore, that point will mainly be described.

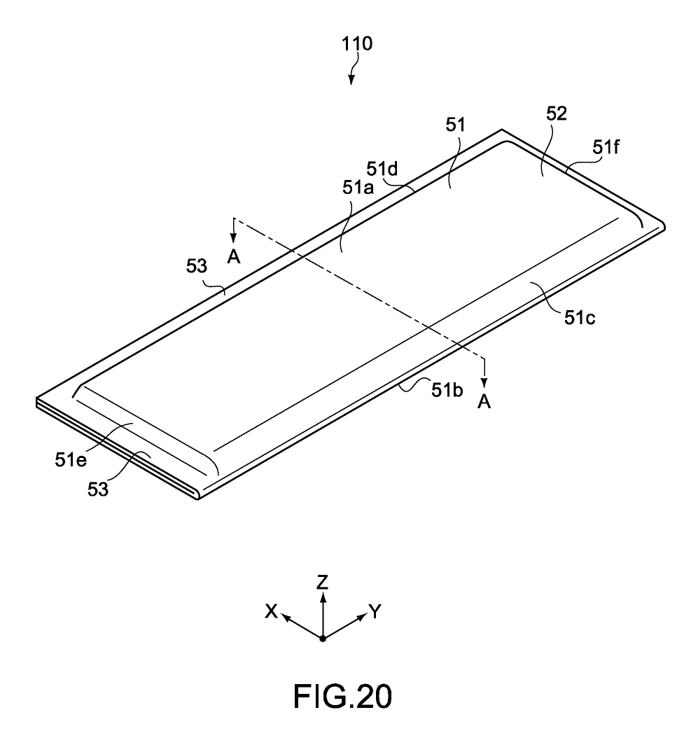

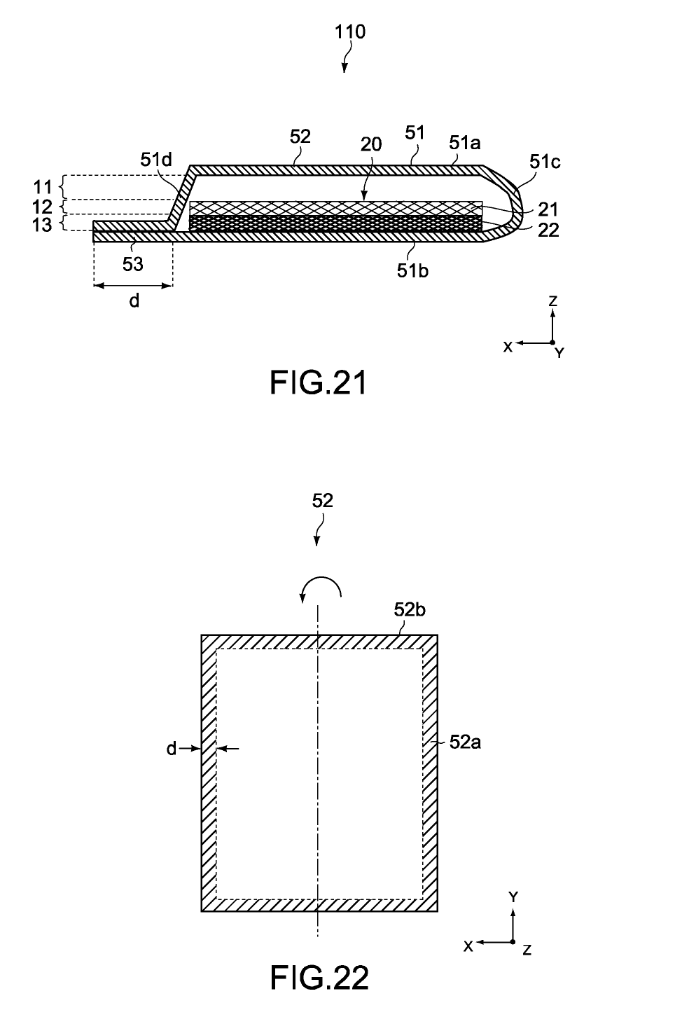

FIG. 20 is a perspective view of a heat-transporting device according to the sixth embodiment. FIG. 21 is a cross-sectional diagram taken along the line A-A of FIG. 20. FIG. 22 is a development view of a plate member that constitutes a vessel of the heat-transporting device.

As shown in FIG. 20, a heat-transporting device 110 includes a thin rectangular plate-like vessel 51 that is elongated in one direction (y-axis direction). The vessel 51 is formed by bending a single plate member 52.

Typically, the plate member 52 is constituted of oxygen-free copper, tough pitch copper, or a copper alloy. However, the present invention is not limited thereto, and the plate member 52 may be constituted of metal other than copper, or other materials having a high heat conductivity may be used instead.

As shown in FIGS. 20 and 21, a side portion 51c of the vessel 51 in a direction along a longitudinal direction (y-axis direction) is curved. In other words, since the vessel 51 is formed by bending substantially the center of the plate member 52 shown in FIG. 22, the side portion 51c is curved. In descriptions below, the side portion 51c may be referred to as curved portion 51c.

The vessel 51 includes bonding portions 53 at a side portion 51d on the other side of the side portion 51c (curved portion 51c) and side portions 51e and 51f along a short-side direction. The bonding portions 53 protrude from the side portions 51d, 51e, and 51f. At the bonding portions 53, the bent plate member 52 is bonded. The bonding portions 53 correspond to a bonding area 52a of the plate member 52 shown in FIG. 22 (area indicated by slashes in FIG. 22). The bonding area 52a is an area within a predetermined distance d from an edge portion 52b of the plate member 52.

Examples of the method of bonding the bonding portions 53 (bonding area 52a) include a diffusion bonding method, an ultrasonic bonding method, a brazing method, and a welding method, but the bonding method is not particularly limited.

Inside of the vessel 51 of the heat-transporting device 110 is hollow on an upper portion 51a side, and the laminated body 20 is disposed on a lower portion 51b side. The laminated body 20 is formed by laminating the upper-layer mesh member 21 and the lower-layer mesh member 22. The vapor-phase flow path 11 is formed by a cavity formed on the upper portion 51a side of the vessel 51. Moreover, the intermediate layer 12 is constituted of the upper-layer mesh member 21 and the liquid-phase flow path 13 is constituted of the lower-layer mesh member 22.

It should be noted that the structures of the vapor-phase flow path 11, the intermediate layer 12, and the liquid-phase flow path 13 are not limited to those shown in FIG. 21. For example, the columnar portions 5 may be provided in the vapor-phase flow path 11 or the vapor-phase flow path 11 may be constituted of the vapor-phase mesh member 34. Moreover, the laminated body 20 may be constituted of three or more layers. All the structures of the vapor-phase flow path 11, the intermediate layer 12, and the liquid-phase flow path 13 described in the above embodiments are applicable to the sixth embodiment. The same holds true for embodiments to be described later.

(Method of Producing Heat-Transporting Device)

Next, a method of producing a heat-transporting device 110 will be described.

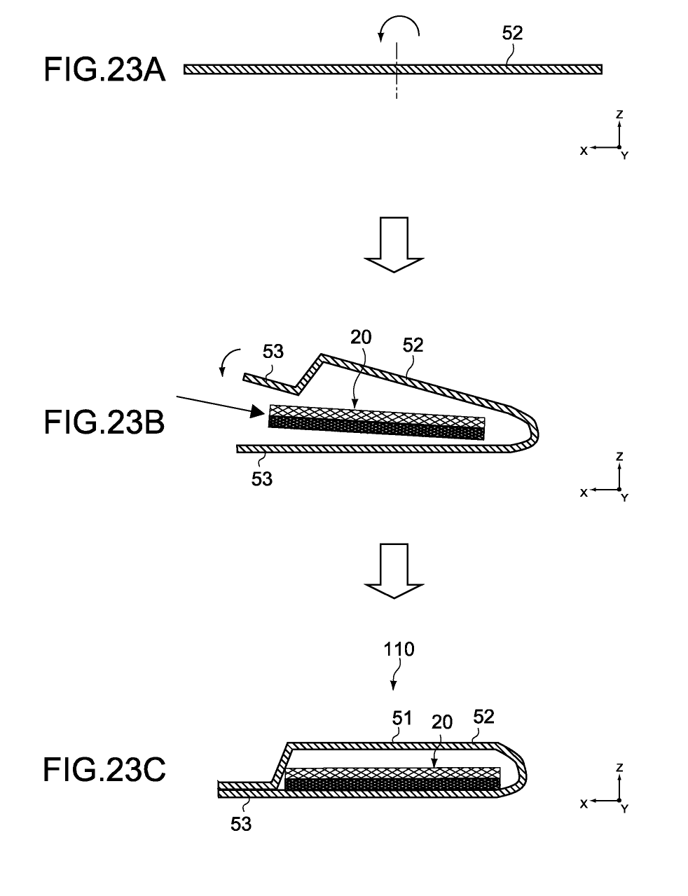

FIG. 23 are diagrams showing the method of producing a heat-transporting device.

As shown in FIG. 23A, the plate member 52 is prepared first. Then, the plate member 52 is bent at substantially the center thereof.

After the plate member 52 is bent to a predetermined angle, the laminated body 20 is inserted between the bent plate member 52 as shown in FIG. 23B. It should be noted that it is also possible to set the laminated body 20 at a predetermined position on the plate member 52 before the plate member 52 is bent.

After the laminated body 20 is inserted between the bent plate member 52, the plate member 52 is bent further so as to enclose the laminated body 20 inside as shown in FIG. 23C. Then, the bonding portions 53 (bonding area 52a) of the bent plate member 52 are bonded. As the method of bonding the bonding portions 53, a diffusion bonding method, an ultrasonic bonding method, a brazing method, a welding method, and the like are used as described above.

Since the vessel 51 is constituted of a single plate member 52 in the heat-transporting device 110 according to the sixth embodiment, costs can be reduced. Further, although, when the vessel is constituted of two or more members, those members need to be aligned in position, alignment of positions of the members is not necessary in the heat-transporting device 110 of the sixth embodiment. Therefore, the heat-transporting device 110 can be produced with ease. It should be noted that although a structure in which the plate member 52 is bent with an axis along the longitudinal direction (y-axis direction) is shown, it is also possible for the plate member 52 to be bent with an axis along the short-side direction (x-axis direction).

### Modified Example

Next, a modified example of the heat-transporting device according to the sixth embodiment will be described.

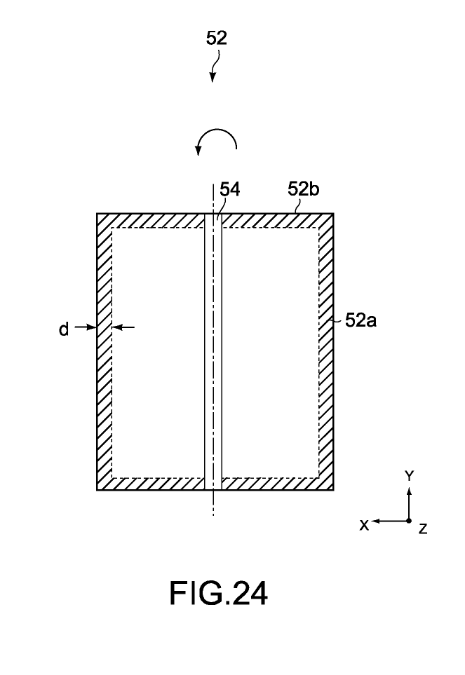

FIG. 24 is a development view of the plate member for explaining the modified example.

As shown in FIG. 24, the plate member 52 includes a groove 54 at a center thereof along a longitudinal direction (y-axis direction). The groove 54 is formed by, for example, press work or etching, but the method of forming the groove 54 is not particularly limited.

By providing the groove 54 on the plate member 52, the plate member 52 can be bent easily. As a result, it becomes easier to produce the heat-transporting device 110.

### Seventh Embodiment

Next, a seventh embodiment of the present invention will be described. It should be noted that in the seventh embodiment, points different from those of the sixth embodiment above will mainly be described.

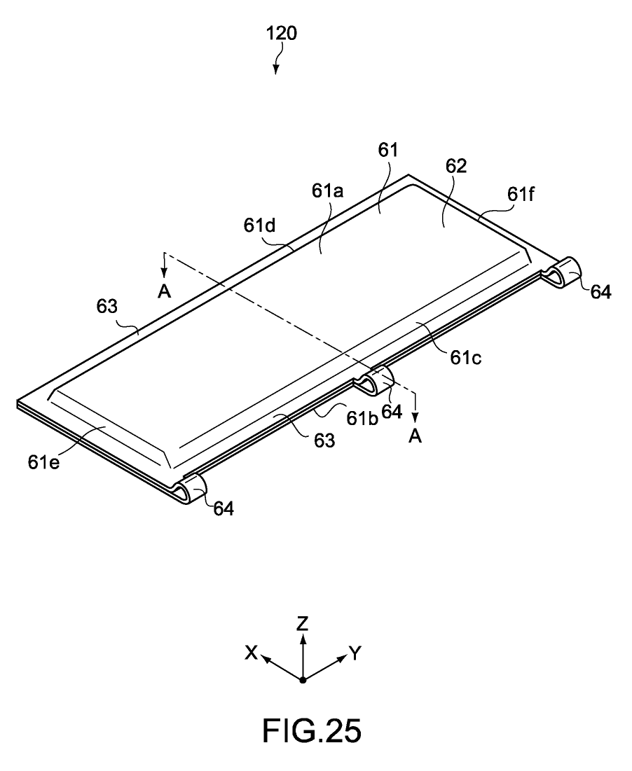

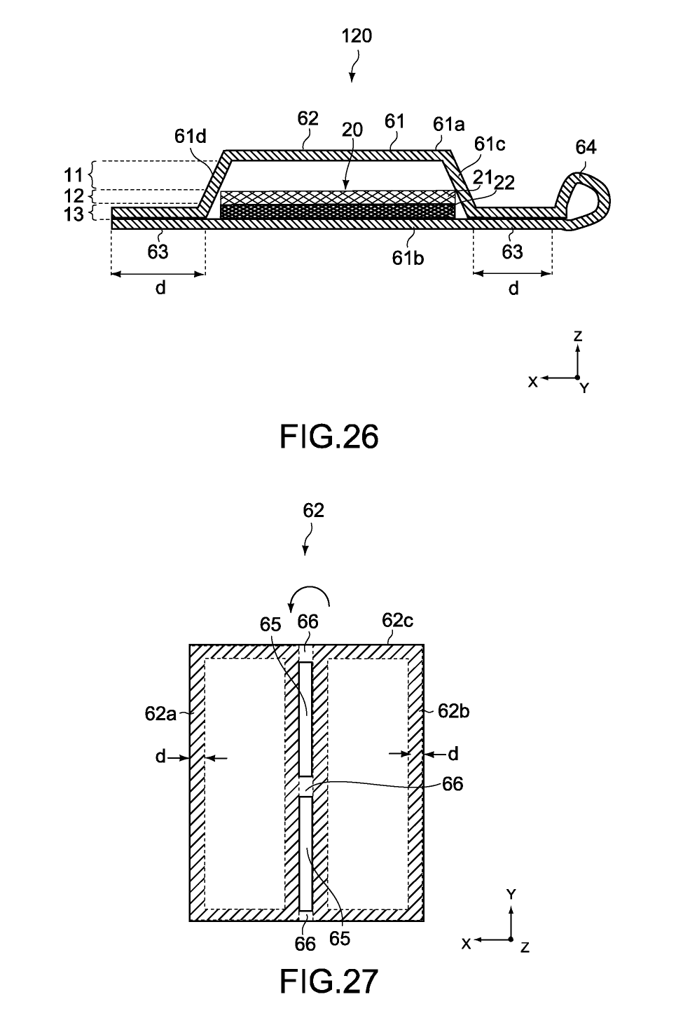

FIG. 25 is a perspective view of a heat-transporting device according to the seventh embodiment. FIG. 26 is a cross-sectional diagram taken along the line A-A of FIG. 25. FIG. 27 is a development view of a plate member that constitutes a vessel of the heat-transporting device.

As shown in FIGS. 25 and 26, a heat-transporting device 120 includes a thin rectangular plate-like vessel 61 that is elongated in one direction (y-axis direction).

The vessel 61 is formed by bending a plate member 62 shown in FIG. 27 at a center thereof. The plate member 62 is provided with two openings 65 near the center along a longitudinal direction thereof.

The vessel 61 includes bonding portions 63 at side portions 61c and 61d in a direction along the longitudinal direction (y-axis direction) and side portions 61e and 61f in a direction along a short-side direction (x-axis direction). The vessel 61 is formed by bonding the bonding portions 63. The bonding portions 63 correspond to bonding areas 62a and 62b of the plate member 62 shown in FIG. 27 (area indicated by slashes in FIG. 27). The bonding areas 62a and 62b are arranged axisymmetrically on left- and right-hand sides of the plate member 62. The bonding areas 62a and 62b are areas within a predetermined distance d from an edge portion 62c or the openings 65 of the plate member 62.

The bonding portion 63 provided at the side portion 61c of the vessel 61 includes three protrusions 64. The three protrusions 64 are bent. The three protrusions 64 correspond to areas 66 each between the opening 65 and the edge portion 62c and an area 66 between the two openings 65 on the plate member 62 shown in FIG. 27.

Inside of the vessel 61 is hollow on an upper portion 61a side, and this cavity constitutes the vapor-phase flow path 11. Moreover, the upper-layer mesh member 21 constitutes the intermediate layer 12, and the lower-layer mesh member 22 constitutes the liquid-phase flow path 13.

Since the openings 65 are formed on the plate member 62 in the heat-transporting device 120 of the seventh embodiment, the plate member 62 can be bent with ease. As a result, it becomes easier to produce the heat-transporting device 120.

It is also possible to form on the plate member 62 a groove in the areas 66 each between the opening 65 and the edge portion 62c and the area 66 between the two openings 65 by press work, for example. Accordingly, the plate member 62 can be bent more easily. It should be noted that although a structure in which the plate member 62 is bent with an axis along the longitudinal direction (y-axis direction) is shown, it is also possible for the plate member 62 to be bent with an axis along the short-side direction (x-axis direction).

(Electronic Apparatus)

Next, an electronic apparatus including the heat-transporting device 10 (or 50 to 120; the same holds true for descriptions below) described in the corresponding embodiment above will be described. This embodiment exemplifies a laptop PC as the electronic apparatus.

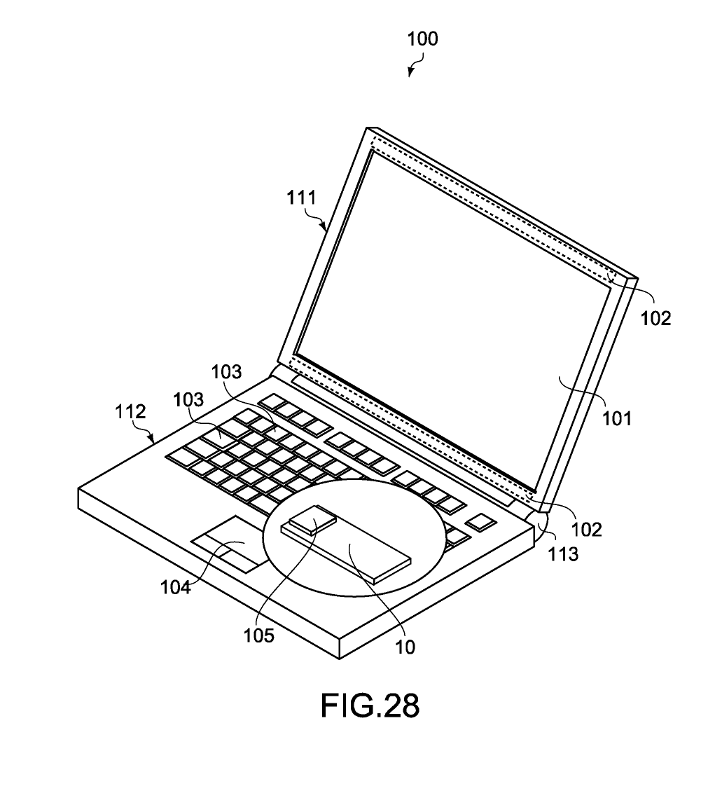

FIG. 28 is a perspective view of a laptop PC 100. As shown in FIG. 28, the laptop PC 100 includes a first casing 111, a second casing 112, and a hinge portion 113 that rotatably supports the first casing 111 and the second casing 112.

The first casing 111 includes a display portion 101 and edge-light-type backlights 102 that irradiate light onto the display portion 101. The backlights 102 are respectively provided on upper and lower sides inside the first casing 111. The backlights 102 are each formed by arranging a plurality of white-color LEDs (Light-emitting Diodes) on a copper plate, for example.

The second casing 112 includes a plurality of input keys 103 and a touchpad 104. The second casing 112 also includes a built-in control circuit board (not shown) on which electronic circuit components such as a CPU 105 are mounted.

Inside the second casing 112, the heat-transporting device 10 is set so as to come into contact with the CPU 105. In FIG. 28, a plane of the heat-transporting device 10 is illustrated to be smaller than that of the second casing 112. However, the heat-transporting device 10 may have an equivalent plane size as the second casing 112.

Alternatively, the heat-transporting device 10 may be set inside the first casing 111 while being in contact with the copper plates constituting the backlights 102. In this case, the heat-transporting device 10 is provided plurally in the first casing 111.

As described above, due to high heat-transporting performance, the heat-transporting device 10 can readily transport heat generated in the CPU 105 or the backlights 102. Accordingly, heat can be readily radiated outside the laptop PC 100. Moreover, since an internal temperature of the first casing 111 or the second casing 112 can be made uniform by the heat-transporting device 10, low-temperature burn can be prevented.

Furthermore, since high heat-transporting performance is realized in a thin heat-transporting device 10, thinning of the laptop PC 100 can also be realized.

FIG. 28 has exemplified the laptop PC as the electronic apparatus. However, the electronic apparatus is not limited thereto, and other examples of the electronic apparatus include audiovisual equipment, a display apparatus, a projector, game equipment, car navigation equipment, robot equipment, a PDA (Personal Digital Assistance), an electronic dictionary, a camera, a cellular phone, and other electrical appliances.

The heat-transporting device and electronic apparatus described heretofore are not limited to the above embodiments, and various modifications are possible.

The above embodiments have described cases where the liquid-phase flow path 13 is constituted of a mesh member. However, the present invention is not limited thereto, and a part of the liquid-phase flow path 13 may be formed of a material other than the mesh member. Examples of the material other than the mesh member include felt, a metal form, a thin line, a sintered body, and a microchannel including fine grooves.

The present application contains subject matter related to that disclosed in Japanese Priority Patent Application JP 2008-328871 filed in the Japan Patent Office on Dec. 24, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A heat-transporting device, comprising:
a working fluid to transport heat using a phase change;
a vessel to seal in the working fluid;
a vapor-phase flow path to cause the working fluid in a vapor phase to circulate inside the vessel;
a liquid-phase flow path that includes a first mesh member having a first mesh number and causes the working fluid in a liquid phase to circulate inside the vessel; and
an intermediate layer that includes a second mesh member and is interposed between the liquid-phase flow path and the vapor-phase flow path, the second mesh member being laminated on the first mesh member and having a second mesh number smaller than the first mesh number.

2. The heat-transporting device according to claim 1,
wherein the vapor-phase flow path includes a third mesh member having a third mesh number smaller than the second mesh number.

3. The heat-transporting device according to claim 2,
wherein the liquid-phase flow path further includes one or more mesh members that are disposed below the first mesh member such that mesh numbers thereof decrease stepwise from a lower layer adjacent to the vessel to an upper layer adjacent to the intermediate layer.

4. The heat-transporting device according to claim 3,
wherein the mesh numbers of the mesh members except the mesh number of the mesh member positioned at the very bottom decrease stepwise from the lower layer to the upper layer.

5. The heat-transporting device according to claim 1,
wherein the vessel is plate-like.

6. The heat-transporting device according to claim 5,
wherein the vessel includes a first side that is in contact with a heat source and a second side on the other side of the first side,
wherein the vapor-phase flow path is disposed on the second side, and
wherein the liquid-phase flow path is disposed on the first side.

7. The heat-transporting device according to claim 5,
wherein the vessel is formed by bending a plate member so that the first mesh member and the second mesh member are sandwiched by the bent plate member.

8. The heat-transporting device according to claim 7,
wherein the plate member includes an opening in an area where the plate member is bent.

9. A heat-transporting device, comprising:
a working fluid to transport heat using a phase change;
a vessel to seal in the working fluid;
a vapor-phase flow path that includes a first capillary radius and causes the working fluid in a vapor phase to circulate inside the vessel;
a liquid-phase flow path that includes a second capillary radius and causes the working fluid in a liquid phase to circulate inside the vessel; and
an intermediate layer that includes a third capillary radius larger than the second capillary radius but smaller than the first capillary radius and is interposed between the liquid-phase flow path and the vapor-phase flow path.

10. An electronic apparatus, comprising:
a heat source; and
a heat-transporting device including
a working fluid to transport heat of the heat source using a phase change,
a vessel to seal in the working fluid,
a vapor-phase flow path to cause the working fluid in a vapor phase to circulate inside the vessel,
a liquid-phase flow path that includes a first mesh member having a first mesh number and causes the working fluid in a liquid phase to circulate inside the vessel, and
an intermediate layer that includes a second mesh member and is interposed between the liquid-phase flow path and the vapor-phase flow path, the second mesh member being laminated on the first mesh member and having a second mesh number smaller than the first mesh number.

11. An electronic apparatus, comprising:
a heat source; and
a heat-transporting device including
a working fluid to transport heat of the heat source using a phase change,
a vessel to seal in the working fluid,
a vapor-phase flow path that includes a first capillary radius and causes the working fluid in a vapor phase to circulate inside the vessel,
a liquid-phase flow path that includes a second capillary radius and causes the working fluid in a liquid phase to circulate inside the vessel, and
an intermediate layer that includes a third capillary radius larger than the second capillary radius but smaller than the first capillary radius and is interposed between the liquid-phase flow path and the vapor-phase flow path.
